(19) United States
(12) Patent Application Publication
(10) Pub. No.: US 2012/0126265 A1
(43) Pub. Date: May 24, 2012

(54) LED PACKAGE

(75) Inventors: SHIH-YUAN HSU, Hukou (TW); JUNG-HSI FANG, Hukou (TW)

(73) Assignee: ADVANCED OPTOELECTRONIC TECHNOLOGY, INC., Hsinchu Hsien (TW)

(21) Appl. No.: 13/227,611

(22) Filed: Sep. 8, 2011

(30) Foreign Application Priority Data
Nov. 18, 2010 (CN) 201010548184.7

(51) Int. Cl. H01L 33/50

(52) U.S. Cl. 257/98; 257/E33.061

(57) ABSTRACT

An exemplary LED package includes a substrate, an electric layer formed on the substrate, an LED chip mounted on the substrate and electrically connected with the electric layer, a first fluorescent layer and a second fluorescent layer. The first fluorescent encloses the LED chip and includes first phosphorous compounds. The second fluorescent covers the first fluorescent layer and includes second phosphorous compounds different from the first phosphorous compounds. The second fluorescent layer is detachably mounted at an outside of the first fluorescent layer.

### BACKGROUND

1. Technical Field

The present disclosure relates to semiconductor packages, and particularly to an LED (light emitting diode) package with improved optical effect.

2. Description of the Related Art

A typical LED package includes a substrate, an LED chip disposed on the substrate and an encapsulation material encapsulating the LED chip. The encapsulation material includes a resin and phosphorous compounds doped within the resin, which are configured to turn a portion of light emitted from the LED chip into a light with a different color. The light with a different color and the other portion of the light from the LED chip are mixed together to obtain a light with a desired color.

However, the encapsulation material is usually fixedly affixed to the substrate when the LED package is formed. Thus, the phosphorous compounds doped within the encapsulation material of the LED package can not be replaced when the LED package is formed, which result in that the color of the light emitted from the LED package can not be changed according to different requirements. The unchangeable color emitted from the LED package limits the use of the LED package.

Therefore, it is desirable to provide an LED package which can overcome the described limitations.

### BRIEF DESCRIPTION OF THE DRAWINGS

FIG. 1 is a schematic, cross section of an LED package in accordance with a first exemplary embodiment of the present disclosure.

FIG. 2 is a schematic, cross section of an LED package in accordance with a second exemplary embodiment of the present disclosure.

FIG. 3 is a schematic, cross section of an LED package in accordance with a third exemplary embodiment of the present disclosure.

### DETAILED DESCRIPTION

Embodiments of an LED package as disclosed are described in detail here with reference to the drawings.

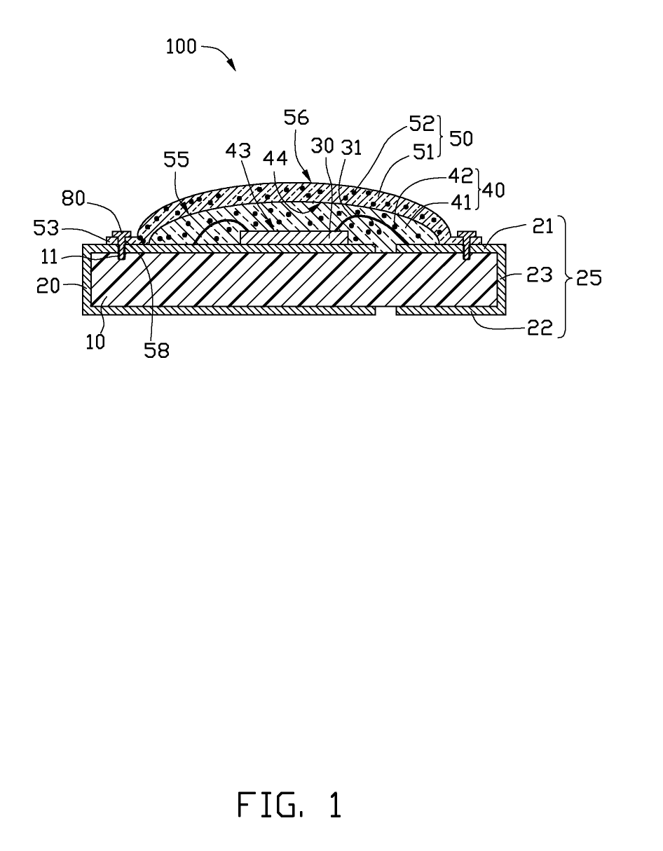

Referring to FIG. 1, an LED package 100 according to a first embodiment is shown. The LED package 100 includes a substrate 10, an electric layer 20 formed on the substrate 10, an LED chip 30 mounted on the substrate 10 and electrically connected with the electric layer 20, a first fluorescent layer 40 enclosing the LED chip 30 and a second fluorescent layer 50 covering the first fluorescent layer 40.

The substrate 10 is made of thermally conductive and electrically insulating material such as ceramics, epoxy, silicone, silicon oxide or a mixture thereof. The substrate 10 defines two screw holes 11 at a periphery portion thereof. Each of the screw holes 11 is a blind hole, extending vertically from a top surface of the substrate 10 toward a bottom surface of the substrate 10, and forms a screw thread at an inner surface thereof.

The electric layer 20 includes a pair of electrodes 25 located at two opposite ends of the substrate 10, respectively. Each of the electrodes 25 is about U-shaped, and includes a first horizontal portion 21 formed at the top surface of the substrate 10, a second horizontal portion 22 parallel to the first horizontal portion 21 and formed at the bottom surface of the substrate 10 and a vertical portion 23 connected between the first and second horizontal portions 21, 22. The two electrodes 25 are spaced from each other and electrically insulated from each other. The electric layer 20 can be formed on the substrate 10 by sputtering, electroplating, electroforming, deposition or other related known methods.

In this embodiment, the LED chip 30 is a blue LED chip which can emit blue light. The LED chip 30 is fixed on one of the electrodes 25 with a bottom surface thereof contacting the first horizontal portion 21 of the one of the electrodes 25. The LED chip 30 electrically connects the electrodes 25 via a pair of electric wires 31. Alternatively, the LED chip 30 can be other types of LED chips such as a red LED chip which can emit red light or a green LED chip which can emit green light, and the LED chip 30 can be electrically connected with the electrodes 25 via flip chip.

The first fluorescent layer 40 includes a resin 41 and first phosphorous compounds 42 doped within the resin 41, which are configured to turn a portion of light emitted from the LED chip 30 into a light with a different color. The light with a different color and another portion of the light from the LED chip 30 are mixed together to obtain a light with a desired color. The resin 41 includes a first light incident surface 43 matched with an outer shape of the LED chip 30 and a first light exit surface 44 opposite to the light incident surface 43. In this embodiment, the first phosphorous compounds 42 are yellow phosphorous compounds which are chosen from garnet based phosphors, silicate-based phosphors, former portland-based phosphors, sulfide-based phosphors, thio-salt-based phosphors and gallium nitride-based phosphors.

Alternatively, the first fluorescent layer 40 can include a resin 41 with no phosphorous compound doped therein and the first phosphorous compounds 42 are layered on the first light exit surface 44 of the resin 41.

The second fluorescent layer 50 is detachably mounted at an out side of the first fluorescent layer 40. The second fluorescent layer 50 includes a transparent lens 51, second phosphorous compounds 52 doped within the transparent lens 51 and a fixing portion 53 extending outwardly from a periphery side of the transparent lens 51. The second phosphorous compounds 52 are configured to turn a portion of light emitted from the LED chip 30 into a light with a different color. The light with a different color and the other portion of the light from the LED chip 30 are mixed together to obtain a light with a desired color. The transparent lens 51 includes a second light incident surface 55 matched with the first light exit surface 44 of the first fluorescent layer 40 and a second light exit surface 56 substantially parallel to and spaced from the second light incident surface 55. Both of the second light incident surface 55 and the second light exit surface 56 are convex, smooth surface. In this embodiment, the second phosphorous compounds 52 doped within the transparent lens 51 are red phosphorous compounds.

The fixing portion 53 defines two through holes 58 therethrough, located corresponding to the screw holes 11 of the substrate 10 respectively. When assembled, the second fluorescent layer 50 covers the first fluorescent layer 40 with the second light incident surface 55 tightly contacted the first light exit surface 44, the fixing portion 53 of the second fluorescent layer 50 contacts the substrate 10 with the through holes 58 aligned with the screw holes 11, respectively. Then fasteners 80, such as bolts are brought to respectively extend through the through holes 58 of the fixing portion 53 and screwed into the screw holes 11 of the substrate 10 to fix the second fluorescent layer 50 in position.

When the LED package 100 is used, light emitted from the LED chip 30 travels through the first fluorescent layer 40 and the second fluorescent layer 50 in sequence, and finally exit the LED package 100 via the second light exit surface 56 of the second fluorescent layer 50. When the light emitted from the LED chip 30 travels through the first fluorescent layer 40, a portion of the blue light emitted from the LED chip 30 and incident on the yellow phosphorous compounds is turned into yellow light; a portion of the blue light of the LED chip 30 is mixed together with the yellow light to cooperatively form a first white light which has a first color temperature. Simultaneously, another portion of the light emitted from the LED chip 30 which travels through the first fluorescent layer 40 and is incident on the red phosphorous compounds is turned into red light, and another portion of the blue light of the LED chip 30 after traveling through the first fluorescent layer 40 is mixed together with the red light to cooperatively form a second white light which has a second color temperature. The second color temperature is different from the first color temperature, and the second white light and the first white light are mixed together to improve a color temperature of the white light provided by the LED package 100.

Understandably, the second fluorescent layer 50 is easily detached from the substrate 10 by loosening the fasteners 80, and another second fluorescent layer which includes a transparent lens with different phosphorous compounds, such as green phosphorous compounds doped therein can be assembled to the substrate 10 according to a different requirement. Due to the second fluorescent layer 50 can be assembled to or detached from the LED package 100 easily, the LED package 100 has better versatility by replacing different second fluorescent layers.

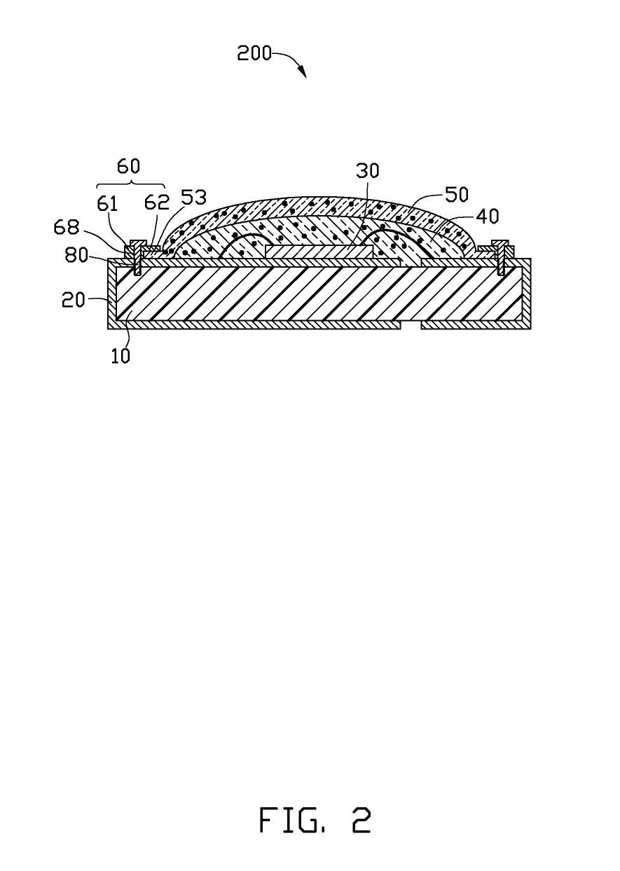

Referring to FIG. 2, an LED package 200 according to a second exemplary embodiment is shown. The LED package 200 is different from the LED package 100 only in that the LED package 200 includes a second fluorescent layer 50 with no through holes defined in the fixing portion 53, and the LED package 200 further includes a plurality of connecting blocks 60 for connecting the second fluorescent layer 50 to the substrate 10. Each of the connecting blocks 60 includes a mounting portion 61 defining a through hole 68 therein and a pressing portion 62 extending inwardly from a top end of the mounting portion 61. The pressing portion 62 has a thickness less than that of the mounting portion 61, such that a cutout is defined under the pressing portion 61. When the second fluorescent layer 50 is assembled to the substrate 10, the connecting blocks 60 are located at two opposite sides of the second fluorescent layer 50 with the through holes 68 of the mounting portions 61 aligned with the screw holes 11 of the substrate 10, respectively, and the pressing portion 62 presses the fixing portion 53 of the second fluorescent layer 50 with the fixing portion 53 received in the cutout thereof. Then fasteners 80 respectively traverse through the through holes 68 and further are screwed into the screw holes 11 to thereby fix the second fluorescent layer 50 in position.

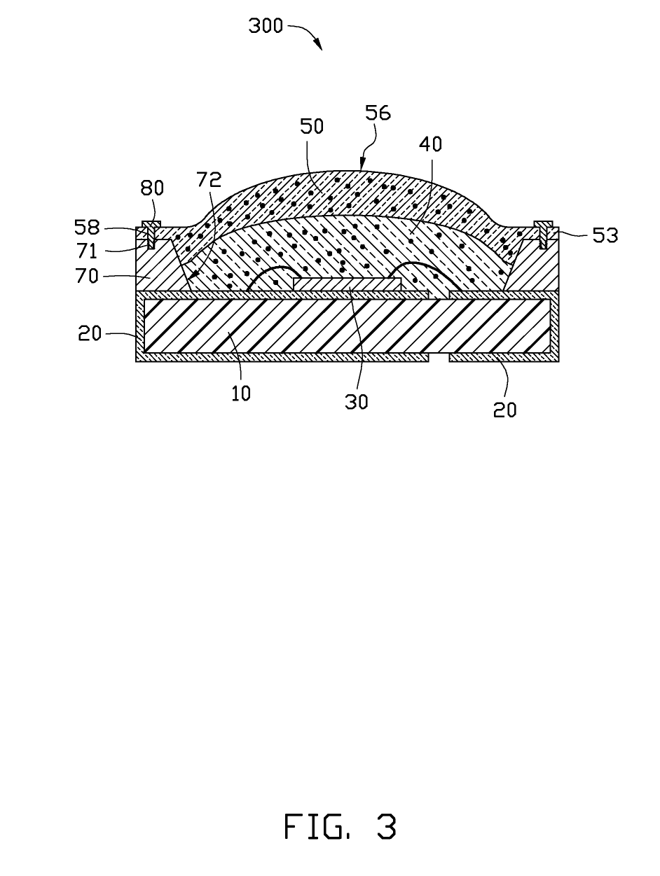

Referring to FIG. 3, an LED package 300 according to a third exemplary embodiment is shown. The LED package 300 is different from the LED package 100 only in that the LED package 300 further includes an annular reflecting cup 70 around the LED chip 30 and on the substrate 10, the substrate 10 has no screw holes defined therein, and the annular reflecting cup 70 defines two screw holes 71 corresponding to the through holes 58 of the second fluorescent layer 50, respectively. The reflecting cup 70 includes an inclined reflecting surface 72 surrounding the LED chip 30, for reflecting light emitted from the LED chip 30 towards the second light exit surface 56 of the second fluorescent layer 50 to obtain a concentrated high-brightness light.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. An LED package, comprising:
a substrate;
an electric layer formed on the substrate;
an LED chip mounted on the substrate and electrically connected with the electric layer;
a first fluorescent layer enclosing the LED chip and comprising first phosphorous compounds; and
a second fluorescent layer covering the first fluorescent layer and comprising second phosphorous compounds different from the first phosphorous compounds, the second fluorescent layer being detachably mounted at an out side of the first fluorescent layer.

2. The LED package as claimed in claim 1, wherein the second fluorescent layer comprises a transparent lens, and the second phosphorous compounds are doped within the transparent lens.

3. The LED package as claimed in claim 2, wherein the second fluorescent layer further comprises a fixing portion extending outwardly from the transparent lens, and the second fluorescent layer is detachably connected to the substrate via the fixing portion.

4. The LED package as claimed in claim 3, wherein the substrate defines a plurality of screw holes therein, the fixing portion defining a plurality of through holes corresponding to the screw holes, respectively, the second fluorescent layer being fixed on the substrate via fasteners respectively extending through the through holes and screwed into the screw holes.

5. The LED package as claimed in claim 3, further comprising a plurality of connecting blocks, each of the connecting blocks comprising a mounting portion defining a through hole therein and a pressing portion extending inwardly from the mounting portion and pressing the fixing portion of the second fluorescent layer, the substrate defining a plurality of screw holes corresponding the through holes of the connecting blocks, respectively, the second fluorescent layer being fixed on the substrate via fasteners respectively extending through the through holes and screwed into the screw holes.

6. The LED package as claimed in claim 3, further comprising a reflecting cup around the LED chip mounted on the substrate, the reflecting cup defining a plurality of screw holes therein, the fixing portion defining a plurality of through holes corresponding to the screw holes, respectively, the second fluorescent layer being fixed on the substrate via fasteners respectively extending through the through holes and screwed into the screw holes.

7. The LED package as claimed in claim 1, wherein the first fluorescent layer includes a resin, and the first phosphorous compounds are doped within the resin.

8. The LED package as claimed in claim 7, wherein the resin comprises a first light incident surface matched with an outer shape of the LED chip and a first light exit surface opposite to the first light incident surface, the second fluorescent layer comprising a second light incident surface contacting with the first light exit surface and a second light exit surface substantially parallel to and spaced from the second light incident surface.

9. The LED package as claimed in claim 8, wherein light emitted from the LED chip travels through the first fluorescent layer and the second fluorescent layer in sequence and finally exits the LED package via the second light exit surface.

10. An LED package, comprising:
a substrate;
an electric layer formed on the substrate;
an LED chip mounted on the substrate and electrically connected with the electric layer;
a first fluorescent layer enclosing the LED chip, the first fluorescent layer comprising a resin and first phosphorous compounds doped within the resin; and
a second fluorescent layer covering the first fluorescent layer, the second fluorescent layer comprising a transparent lens and second phosphorous compounds different from the first phosphorous compounds and doped within the transparent lens, the second fluorescent layer being detachably mounted at an outer side of the first fluorescent layer.

11. The LED package as claimed in claim 10, wherein the resin comprises a first light incident surface matched with an outer shape of the LED chip and a first light exit surface opposite to the first light incident surface, and the transparent lens comprises a second light incident surface contacted with the first light exit surface and a second light exit surface substantially parallel to and spaced from the second light incident surface, and wherein light emitted from the LED chip travels through the first fluorescent layer and the second fluorescent layer in sequence and finally exits the LED package via the second light exit surface.

12. The LED package as claimed in claim 10, wherein the second fluorescent layer further comprises a fixing portion extending outwardly from the transparent lens, and the second fluorescent layer is detachably connected to the substrate via the fixing portion.

13. The LED package as claimed in claim 12, wherein the substrate defines a plurality of screw holes therein, the fixing portion defining a plurality of through holes corresponding to the screw holes, respectively, the second fluorescent layer being fixed on the substrate via fasteners respectively extending through the through holes and screwed into the screw holes.

14. The LED package as claimed in claim 12, further comprising a plurality of connecting blocks, each of the connecting blocks comprising a mounting portion defining a through hole therein and a pressing portion extending inwardly from the mounting portion and pressing the fixing portion of the second fluorescent layer, the substrate defining a plurality of screw holes corresponding the through holes of the connecting blocks, respectively, the second fluorescent layer being fixed on the substrate via fasteners respectively extending through the through holes and screwed into the screw holes.

15. The LED package as claimed in claim 12, further comprising a reflecting cup around the LED chip and mounted on the substrate, the reflecting cup defining a plurality of screw holes therein, the fixing portion defining a plurality of through holes corresponding to the screw holes, respectively, the second fluorescent layer being fixed on the substrate via fasteners respectively extending through the through holes and screwed into the screw holes.
